(19) United States
(12) Patent Application Publication
(10) Pub. No.: US 2013/0279126 A1
(43) Pub. Date: Oct. 24, 2013

(54) AROMATIC POLYIMIDE FILM, MANUFACTURING METHOD AND APPLICATION THEREOF

(71) Applicant: TAIMIDE TECHNOLOGY INCORPORATION, Hsinchu County (TW)

(72) Inventors: Chung-Yi Chen, Hsinchu County (TW); Wu-Yung Yang, Hsinchu County (TW); Chih-Wei Lin, Hsinchu County (TW)

(73) Assignee: Taimide Technology Incorporation, Hsinchu County (TW)

(21) Appl. No.: 13/670,015

(22) Filed: Nov. 6, 2012

(30) Foreign Application Priority Data
Apr. 20, 2012 (TW) 101114234
Sep. 13, 2012 (TW) 101133551

(51) Int. Cl. C08G 73/10; H05K 7/06; H01L 31/0216; B32B 15/08; B05D 5/12

(52) U.S. Cl. 361/749; 528/353; 428/458; 427/58; 136/256

(57) ABSTRACT

An aromatic polyimide film can be formed from a plurality of monomers comprising an aromatic dianhydride, and a first aromatic diamine selected from a group consisting of formulae (I) and (II):

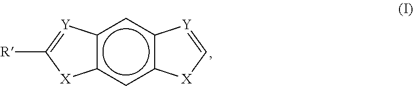

and

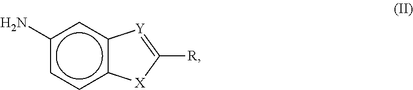

wherein X and Y are respectively selected from the group consisting of oxygen, nitrogen and sulfur, and
R and R′ are respectively selected from the group consisting of NH₂,

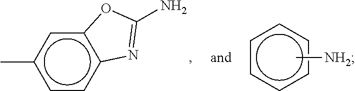

wherein the aromatic polyimide film has an average linear coefficient of thermal expansion equal to or below about 5 ppm/° C. in a temperature range between about 50° C. and about 500° C.

### CROSS-REFERENCE TO RELATED APPLICATIONS

This application claims priority of Taiwan Patent Application No. 101114234 filed on Apr. 20, 2012, and Taiwan Patent Application No. 101133551 filed on Sep. 13, 2012.

### TECHNICAL FIELD

The present invention relates to a polyimide film and its manufacturing method, and more particularly to a polyimide film composed of aromatic monomers.

### BACKGROUND

Owing to its good stability and conversion efficiency, copper indium gallium diselenide (CIGS) has been increasingly used in thin film solar cells as replacement of monocrystalline silicon. In a conventional CIGS solar cell, a glass material (especially soda lime glass) can be used as a substrate, and a metal molybdenum (Mo) can be deposited as an electrode. Moreover, compared to monocrystalline silicon, CIGS semiconductor can be arranged on a flexible substrate (such as polyimide), which makes it more cost-effective to manufacture and provides a larger range of applications.

In order to obtain a CIGS solar cell that has high efficiency, the semiconductor layer has to be formed without any defects. Moreover, a heat treatment of the CIGS semiconductor layer has to be made at a temperature higher than 450° C. to produce a high-quality semiconductor layer with reduced defect density.

The flexible substrate with the CIGS thereon can be efficiently manufactured at a large scale through roll-to-roll processing to fabricate CIGS solar cells. Different factors have to be considered for selecting a suitable flexible substrate, such as the coefficient of thermal expansion (CTE), resistance to heat, size variation under thermal stress, surface roughness and the like. For example, although currently available polyimide can provide heat resistance at a high temperature of about 500° C., its CTE still cannot match with the characteristics of the CIGS semiconductor layer and the metal electrode layer.

Generally, a flexible substrate made of polyimide after appropriate processing can have a CTE equal to about 10 ppm/° C. below 200° C. This CTE value may approximately match with those of the CIGS semiconductor (CTE typically equal to about 9 ppm/° C.) and the Mo electrode layer (CTE typically equal to about 5 ppm/° C.). However, when the temperature becomes higher than 450° C., the CTE of the polyimide can significantly increase to more than 20 ppm/° C., which creates cracks in the electrode layer and causes it to peel off from the semiconductor layer, and even causes warping of the flexible substrate.

Therefore, there is a need for a flexible substrate that can have improved thermal characteristics, and overcome at least the aforementioned issues.

### SUMMARY

The present application describes aromatic polyimide films, manufacturing methods and applications thereof. The aromatic polyimide film can be formed from a plurality of monomers comprising an aromatic dianhydride, and a first aromatic diamine selected from a group consisting of formulae (I) and (II):

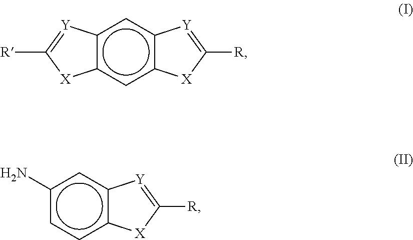

wherein X and Y are respectively selected from the group consisting of oxygen, nitrogen and sulfur, and

R and R′ are respectively selected from the group consisting of NH₂,

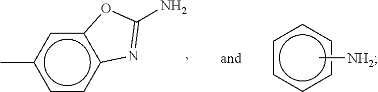

wherein the aromatic polyimide film has an average linear coefficient of thermal expansion equal to or below about 5 ppm/° C. in a temperature range between about 50° C. and about 500° C.

In some embodiments, a method of fabricating an aromatic polyimide film is described. The method includes dissolving an aromatic diamine in an solvent at a temperature equal to or higher than about 40° C., performing condensation polymerization applied on the aromatic diamine and an aromatic dianhydride to obtain a polyamic acid solution, coating a layer of the polyamic acid solution on a support, and baking the coated layer to form an aromatic polyimide film.

### BRIEF DESCRIPTION OF THE DRAWINGS

FIG. 1 is a schematic view illustrating one embodiment in which the aromatic polyimide film can be used in a display;

FIG. 2 is a graph plotting a variation of the LCTE of polyimide films fabricated according to different examples;

FIG. 3 is a schematic view illustrating one laminate embodiment using a polyimide;

FIG. 4A is a schematic view illustrating a laminate formed according to one example;

FIG. 4B is a schematic view illustrating a laminate formed according to a comparative example;

FIG. 5 is a chart illustrating certain measures of thermal expansion taken for different examples of polyimide films; and

FIG. 6 is a chart illustrating the results of measures obtained from certain deformation testing applied on different polyimide films.

### DETAILED DESCRIPTION

The present application describe aromatic polyimide films that have enhanced resistance to heat and a relatively low coefficient of thermal expansion (CTE). Moreover, the coefficient of thermal expansion can be substantially stable and can have almost no temperature dependency in a temperature range between 50° C. and 500° C.

In some embodiments, the present application provides an aromatic polyimide film that can have an average linear coefficient of thermal expansion (LCTE) equal to or smaller than about 5 ppm/° C. in a temperature range between 50° C. and 500° C. More specifically, the average LCTE can be between about 0.5 ppm/° C. and about 4.5 ppm/° C., such as 0.1 ppm/° C., 0.5 ppm/° C., 1.0 ppm/° C., 2.0 ppm/° C., 2.5 ppm/° C., 3.0 ppm/° C., 3.5 ppm/° C., 4.0 ppm/° C., 4.5 ppm/° C., or a value between any of the aforementioned values. In some embodiments, the average LCTE can be equal to about 0.1-0.5 ppm/° C., or 0.4-0.7 ppm/° C. In other embodiments, the average LCTE can be about 2.1-2.8 ppm/° C., or about 2.5-2.9 ppm/° C.

In addition, the LCTE of the aromatic polyimide film can have a variation equal to or smaller than about 11 ppm/° C. in a temperature range between 100° C. and 500° C. For example, the variation can be less than 9, 8, 6, 4, 2 ppm/° C. and the like. In some embodiments, the variation of the LCTE can be less than 8 ppm/° C., more specifically less than 4 ppm/° C. The variation of the LCTE can be derived as a difference between a maximum value and a minimum value of the LCTE in a temperature range between 100° C. and 500° C.

Monomers used for forming the aromatic polyimide film can include an aromatic dianhydride, a first aromatic diamine, and a second aromatic diamine. The second aromatic diamine can be optionally added depending on the desired properties for the film. The aromatic polyimide film can be produced by condensation polymerization of the monomers. The molar ratio of the dianhydrides to diamines is about 1:1, e.g., about 0.90:1.10 or about 0.98:1.02.

The aromatic dianhydride can be selected from 3,3′,4,4′-biphenyl tetracarboxylic dianhydride (BPDA), pyromellitic dianhydride (PMDA), 3,3′,4,4′-benzophenone tetracarboxylic dianhydride (BTDA), 2,2′-bis-(3,4-dicarboxyphenyl)hexafluoropropane (6FDA), 4,4′-oxydiphthalic anhydride (ODPA), 3,3′,4,4′-diphenylsulfone tetracarboxylic dianhydride (DSDA), bis(3,4-dicarboxyphenyl)sulfone, 5(2,5-dioxotetrahydrol)-3-methyl-3-cyclohexane-1,2-dicarboxylic anhydride (such as B-4400), ethylene glycol bis(anhydro-trimellitate) (such as TMEG-200, TMEG-100), 2,3,3′,4′-biphenyl tetracarboxylic anhydride and the like, which can be used alone or in combination.

In some examples of implementation, the aromatic dianhydride can be any of BPDA, PMDA, ODPA, 6FDA, and BTDA, or a combination thereof. More particularly, PMDA can be exemplary used as the aromatic dianhydride.

The first aromatic diamine can be selected from a group consisting of the following structure (I) and (II):

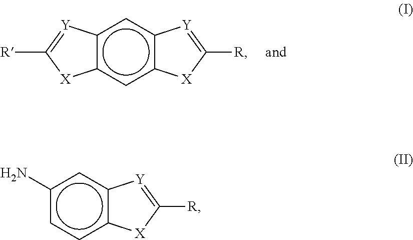

wherein X and Y in the formulae (I) and (II) can be any of oxygen (O), nitrogen (N) and sulfur (S) elements, and X and Y can be identical or different from to each other; and

R and R′ can be any of NH₂,

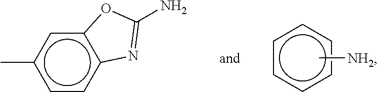

and R and R′ can be identical or different from each other.

Any of the aforementioned compounds (I) and (II) can be used alone or in combination as the first aromatic diamine(s). In some embodiments, the compound (II) can be used as the first aromatic diamine. X and Y in the compound (II) can be respectively oxygen and nitrogen, and R can be

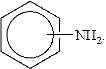

For example, one species of the compound (II) that can be used as diamine may be 6-amino-2-(p-aminophenyl)benzoxazole (PBOA).

In some embodiments, the first aromatic diamine can contain a benzoxazole functional group, i.e.,

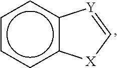

wherein X can be oxygen, and Y can be nitrogen.

In some embodiments, the first aromatic diamine can be used alone. In other embodiments, the first aromatic diamine can be used in combination with the second aromatic diamine: e.g., the molar ratio of the first aromatic diamine can be equal to or greater than about 15 mol % based on the total amount of diamines, and the molar ratio of the second aromatic diamine can be equal to or less than about 85 mol % based on the total amount of diamines.

The second aromatic diamine can be selected from p-phenylenediamine (PDA), 4,4′-oxydianiline (4,4′-ODA), diaminodiphenyl ether (3,4-DAPE), diaminodiphenyl sulfone (DDS), 4,4′-diamino-triphenylamine and the like, which can be used alone or in combination. In some implementation, the second aromatic diamine can be exemplary PDA, 4,4′-ODA, or a combination thereof.

When the first aromatic diamine is used in combination with the second aromatic diamine, the molar ratio of the first to the second aromatic diamines can be about 15-99:85-1, such as 15-95:85-5. More specifically, the molar ratio of the first to the second aromatic diamines can be about 15-80:85-20, i.e., the first aromatic diamine can be about 15 mol % to about 80 mol % of the total amount of diamines (such as 15, 20, 30, 40, 50, 65, 75, 80 mol %, or an intermediate value between any two of the aforementioned values), and the second aromatic diamine can be about 20 mol % to about 85 mol % of the total amount of diamines (such as 20, 25, 35, 50, 60, 70, 80, 85 mol %, or an intermediate value between any two of the aforementioned values).

The aromatic polyimide film can be prepared by the following steps. First, the first and the second aromatic diamines can be added into a solvent and dissolved at a temperature equal to or higher than about 40° C. For example, the solvent can be heated to about 40° C., 42° C., 45° C., 50° C. and the like. The aromatic dianhydride then can be incorporated into the solvent so that condensation polymerization can occur to obtain a polyamic acid solution (“PAA solution”).

The solvent can be a non-protonic polar solvent. For economic considerations and ease of operation, the solvent can have a relatively low boiling point (e.g., below about 225° C.), so that the polyimide film can be dried at a suitable temperature. Examples of suitable solvents can include, without limitation, dimethylacetamide (DMAC), diethylacetamide, N,N′-dimethyl-formamide (DMF), N-methylpyrrolidone (NMP), dimethyl sulfoxide (DMSO), sulfolane, N,N′-dimethyl-N,N′-propylene urea (DMPU), tetramethyl urea (TMU), N-methylcaprolactam, hexamethyl phosphoramide, m-cresol, phenol, p-chlorophenol, 2-chloro-4-hydroxy toluene, diglyme, triglyme, tetraethylene glycol dimethyl ether, dioxane, dioxolane, cyclohexanone, cyclopentanone and butyrolactone, and any combinations thereof. In one example, the used solvent can be DMAC.

In some embodiments, the PAA solution can undergo a thermal ring-closing reaction to form the aromatic polyimide. For example, a layer of the PAA solution can be coated on a glass or a stainless steel plate support. The coated layer can be baked at a temperature between about 60° C. and about 100° C. for 30 minutes to remove most of the solvent, and then heated between about 150° C. and about 450° C. to form the aromatic polyimide film.

In other embodiments, the PAA solution can undergo a chemical ring-closing reaction to form the aromatic polyimide. The PAA solution can be mixed with a dehydrant and a catalyst, and then coated on a glass or a stainless steel plate support. The coated layer can be baked at a temperature between about 60° C. and about 100° C. for 30 minutes to remove most of the solvent, and then heated at a temperature between about 150° C. and about 450° C. to form an aromatic polyimide film.

In the embodiments where the chemical ring-closing reaction is applied, the dehydrant can be selected from aliphatic acid anhydrides (such as acetic anhydride and propionic anhydride), and aromatic acid anhydrides (such as benzoic anhydride and phthalic anhydride), which can be used alone or in combination. For example, acetic anhydride can be used as the dehydrant in an amount between about 2 and about 3 moles per equivalent of the polyamic acid.

The catalyst can be selected from heterocyclic tertiary amines (such as picoline, pyridine, lutidine, quinoilne, isoquinoilne, cinnoline, phthalazine, quinazoline, imidazole, N-methyl-pyrrolidone, N-ethyl-pyrrolidone, N-methyl piperidine, N-ethyl piperidine and the like), aliphatic tertiary amines (such as triethylamine (TEA), tripropylamine, tributylamine, triethanolamine, N,N-dimethyl ethanolamine, triethylenediamine, and N,N-diisopropylethylamine (DIPEA)), and aromatic tertiary amines (such as dimethylaniline), which can be used alone or in combination. For example, one embodiment can use picoline (such as α-picoline, β-picoline or γ-picoline) as the catalyst, and the polyamic acid:dehydrant:catalyst molar ratio can be equal to about 1:2:1.

Other additives can also be incorporated into the PAA solution to confer certain desired properties to the polyimide film. For example, suitable additives can include, without limitation, processing aid, antioxidant, light stabilizer, light extinction coefficient modifier, flame retardant additive, anti-static agent, heat stabilizer, ultraviolet light absorbing agent, reinforcing agent, pigment and the like, which can be used alone or in combination.

The aromatic polyimide film described herein can also be a polybenzoxzole imide (PBI) that includes a benzoxazole functional group. Compared to other polyimide, the PBI can have a smaller average LCTE without the need of additional processing (e.g., mechanical elongation), especially in a temperature range between 50° C. and 500° C. In some embodiments, the PBI can contain 15-85 mol % of a diamine having the benzoxazole functional group, and 85-20 mol % of PDA. This PBI can have a low LCTE, which can be highly stable in a temperature range between about 50° C. and about 500° C.

Examples of applications for the aromatic polyimide film can include flexible support, and substrate for flexible solar cells or displays.

In some applications, a laminate can be formed by disposing a first conductive layer on a first surface of the aromatic polyimide film. If required, the laminate may also include a second conductive layer disposed on a second surface opposite to the first surface of the aromatic polyimide film. The first and/or the second conductive layer can be metal layers selected from Cu, Al, Au, Zn, Ga, In, Sn, Ag, Pd, Ni, Pt, Cr, Mo, W, or any alloy thereof, used individually or in combination. The diamine used in the aromatic polyimide film of the laminate can contain the first aromatic diamine having the following formula (II), i.e.,

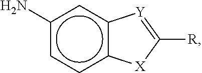

wherein X can be oxygen, Y can be nitrogen, and R can be

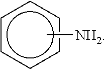

Depending on the desirable properties for the laminate, the diamines can include the aforementioned first aromatic diamine, and a second aromatic diamine selected from any of the following:

(1) PDA, wherein a molar ratio of the first aromatic diamine:PDA is equal to about 99-15:1-85;

(2) 4,4′-ODA, wherein a molar ratio of the first aromatic diamine:4,4′-ODA is equal to about 99-90:1-10; and

(3) a combination of PDA and 4,4′-ODA, wherein a molar ratio of the first aromatic diamine:PDA:4,4′-ODA is equal to about 98-15:1-60:1-25.

In the laminate, the aromatic polyimide film can have a size variation that is less than 0.45% in absolute value in a temperature range between 25° C. and 500° C., more particularly less than 0.4%, for example 0.38%, 0.35%, 0.2%, 0.1%, 0%.

In the laminate, each conductive layer has a thickness equal to or less than about 1 μm, more specifically between about 0.25 μm and about 1 μm, such as 0.75 μm, 0.6 μm, 0.4 μm, 0.3 μm, or an intermediate value between any two of the aforementioned values.

The described laminate can exhibit enhanced size stability, can have good surface flatness and good resistance to heat. Because the laminate is less subjected to thermal deformation, the occurrence of cracks and other structural defects in the conductive layer can be reduced. The laminate may be suitable for use as flexible substrates, e.g., in applications for flexible solar cells and displays.

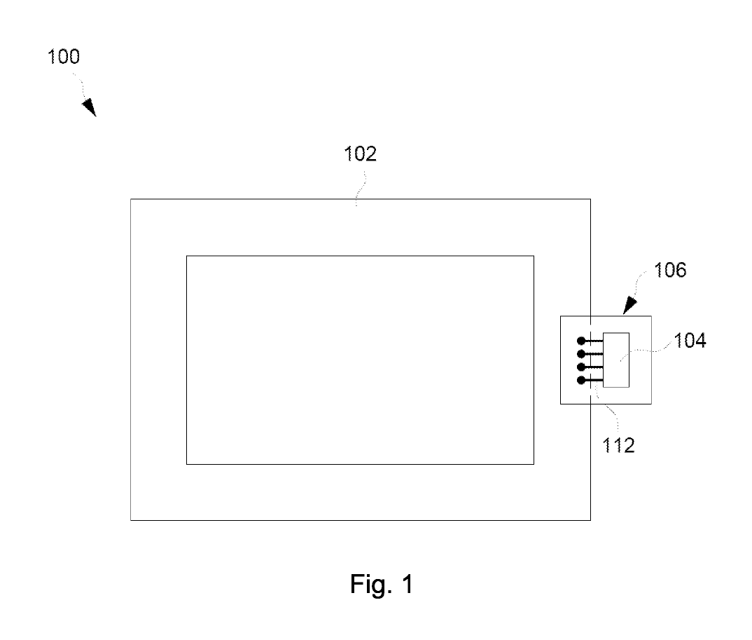

FIG. 1 is a schematic view illustrating one embodiment in which the aromatic polyimide film can be used in a display 100. The display 100 can include a panel 102, and a flexible film 106 having a driving unit 104. The flexible film 106 can include an aromatic polyimide film 110 and a metal layer 112. The metal layer 112 with a circuit pattern printed thereon can be a single layer or multiple layers disposed on the polyimide film 110. The driving unit 104 can be an IC chip disposed on the metal layer 112.

Other applications of the aromatic polyimide film can include, without limitation, flexible printed circuits (FPC), rigid printed boards, flexible-rigid printed boards, LED, TFT-LCD, OLED, AMOLED, portable communication devices, digital cameras, laptops, e-book, tablet PC, plastic chip and the like. Examples of preparation of the aromatic polyimide film is described hereafter.

### Preparation and Properties of Aromatic Polyimide Film

### Example 1.1

About 32.19 g of 6-amino-2-(p-aminophenyl)benzoxazole (PBOA), about 3.86 g of PDA, and about 300 g of DMAC can be incorporated in a 500 ml three-necked flask, and completely dissolved by agitation at a temperature equal to about 40° C. Then, about 38.95 g of PMDA can be added. The weight ratio of the monomers PBOA, PDA and PMDA can be equal to about 20 wt % of the total weight of the reaction solution, and the PBOA:PDA molar ratio can be equal to about 80:20. The reaction mixture can be continuously agitated for 20 hours at a temperature equal to about 25° C. to form a polyamic acid (PAA) solution with a viscosity of about 140,000 cps.

The PAA solution can be coated onto a glass plate support, and then baked in a furnace in a stepwise manner at about 80° C. for 30 minutes to remove the solvent, and then between about 170° C. and about 420° C. for 4 hours to form a PBI polyimide film having a thickness equal to about 38 μm.

### Example 1.2

A polyimide film can be prepared like in Example 1.1, wherein the used monomers can include about 27.30 g of PBOA, about 7.05 g of PDA, and about 40.65 g of PMDA. The weight ratio of the monomers can be equal to about 20 wt % of the total weight of the reaction solution, and the PBOA:PDA molar ratio can be equal to about 65:35.

### Example 1.3

A polyimide film can be prepared like in Example 1.1, wherein the used monomers can include about 21.96 g of PBOA, about 10.53 g of PDA, and about 42.51 g of PMDA. The weight ratio of the monomers can be equal to about 20 wt % of the total weight of the reaction solution, and the PBOA:PDA molar ratio can be equal to about 50:50.

### Example 1.4

A polyimide film can be prepared like in Example 1.1, wherein the used monomers can include about 16.11 g of PBOA, about 14.35 g of PDA, and about 44.55 g of PMDA. The weight ratio of the monomers can be about 20 wt % of the total weight of the reaction solution, and the PBOA:PDA molar ratio can be equal to about 35:65.

### Example 1.5

A polyimide film can be prepared like in Example 1.1, wherein the used monomers can include about 9.67 g of PBOA, about 18.54 g of PDA, and about 46.79 g of PMDA. The weight ratio of the monomers can be about 20 wt % of the total weight of the reaction solution, and the PBOA:PDA molar ratio can be equal to about 20:80.

### Example 1.6

A polyimide film can be prepared like in Example 1.1, wherein the used monomers can include about 7.37 g of PBOA, about 20.4 g of PDA, and about 47.59 g of PMDA. The weight ratio of the monomers can be about 20 wt % of the total weight of the reaction solution, and the PBOA:PDA molar ratio can be equal to about 15:85.

### Example 1.7

About 32.19 g of PBOA, about 3.86 g of PDA and about 300 g of DMAC can be incorporated in a three-necked flask, and completely dissolved by agitation at a temperature equal to about 40° C. Then, about 38.95 g of PMDA can be added. The weight ratio of the monomers PBOA, PDA and PMDA can be about 20 wt % of the total weight of the reaction solution, and the PBOA:PDA molar ratio can be equal to about 80:20. The reaction mixture can be continuously agitated for 20 hours at a temperature of about 25° C. until a PAA solution is formed with a viscosity of about 140,000 cps.

A chemical ring-closing reaction then can be conducted. A dehydrant acetic anhydride and a catalyst picoline then can be added and mixed homogeneously, the PAA:acetic anhydride:picoline molar ratio being equal to about 1:2:1. Subsequently, the PAA solution can be coated onto a glass plate support, and then baked in a furnace in a stepwise manner at about 80° C. for 30 minutes to remove the solvent, and then between about 170° C. and about 420° C. for 4 hours to form a PBI polyimide film having a thickness equal to about 38 μm.

### Example 1.8

A polyimide film can be prepared like in Example 1.7, wherein the used monomers can include about 21.96 g of PBOA, about 10.53 g of PDA, and about 42.51 g of PMDA. The weight ratio of the monomers can be about 20 wt % of the total weight of the reaction solution, and the PBOA:PDA molar ratio can be equal to about 50:50.

### Example 1.9

A polyimide film can be prepared like in Example 1.7, wherein the used monomers can include about 9.67 g of PBOA, about 18.54 g of PDA, and about 46.79 g of PMDA. The weight ratio of the monomers can be about 20 wt % of the total weight of the reaction solution, and the PBOA:PDA molar ratio can be equal to about 20:80.

### Comparative Example 1.1

A polyimide film can be prepared like in Example 1.1, wherein the used monomers can include about 4.52 g of PBOA, about 21.9 g of PDA, and about 48.58 g of PMDA. The weight ratio of the monomers can be about 20 wt % of the total weight of the reaction solution, and the PBOA:PDA molar ratio can be equal to about 9:91.

### Comparative Example 1.2

A polyimide film can be prepared like in Example 1.1, wherein the used monomers can include about 2.55 g of PBOA, about 23.19 g of PDA, and about 49.27 g of PMDA. The weight ratio of the monomers can be about 20 wt % of the total weight of the reaction solution, and the PBOA:PDA molar ratio can be equal to about 5:95.

### Comparative Example 1.3

A polyimide film can be prepared like in Example 1.1, wherein the used monomers can include about 34.64 g of PBOA, about 2.27 g of PDA, and about 38.1 g of PMDA. The weight ratio of the monomers can be about 20 wt % of the total weight of the reaction solution, and the PBOA:PDA molar ratio can be equal to about 88:12.

### Comparative Example 1.4

A polyimide film can be prepared like in Example 1.1, wherein the used monomers can include about 38.109 g of PBOA and about 36.89 g of PMDA. The weight ratio of the monomers can be about 20 wt % of the total weight of the reaction solution.

### Comparative Example 1.5

A polyimide film can be prepared like in Example 1.1, wherein the used monomers can include about 24.85 g of PDA and about 50.15 g of PMDA. The weight ratio of the monomers can be about 20 wt % of the total weight of the reaction solution.

### Comparative Example 1.6

A polyimide film can be prepared like in Example 1.3, wherein the PDA and the PBOA can be dissolved by agitation at a temperature equal to about 30° C. for 20 minutes, and then the PMDA can be added.

### Comparative Example 1.7

A polyimide film can be prepared like in Example 1.3, wherein the PDA and the PBOA can be dissolved by agitation at a temperature equal to about 20° C. for 20 minutes, and then the PMDA can be added.

### Comparative Example 1.8

A polyimide film can be prepared like in Example 1.7, wherein the used monomers can include about 20.15 g of PDA and about 54.85 g of BPDA. The weight ratio of the monomers can be about 20 wt % of the total weight of the reaction solution.

### Comparative Example 1.9

A polyimide film can be prepared like in Example 1.1, wherein the used monomers can include about 20.15 g of PDA and about 54.85 g of BPDA. The weight ratio of the monomers can be about 20 wt % of the total weight of the reaction solution.

### Comparative Example 1.10

A polyimide film can be prepared like in Example 1.7, wherein the used monomers can include about 18.82 g of PDA, about 8.711 g of ODA, and about 47.47 g of PMDA. The weight ratio of the monomers can be about 20 wt % of the total weight of the reaction solution.

Measure of the LCTE

The LCTE can be measured by using a thermal mechanical analyzer TMAQ400 (sold by TA Instruments, Inc.). In a nitrogen atmosphere, a sample of the polyimide film with a surface dimension of about 15 mm×4 mm can be heated from 50° C. to 500° C. at a heating rate equal to about 20° C./min, and then cooled down from 500° C. to 50° C. at a cooling rate equal to about 20° C./min A second heating process can be conducted in the same conditions. A size variation of the sample at 200° C., 350° C. and 500° C. during the second heating can be measured to avoid biasing effects induced by residual stress.

An LCTE can be derived from the following formula:

LCTE (ppm/° C.)=(L−L₀)/{L₀×(T−T₀)}×10⁶=α

wherein L₀ is the sample length at the temperature 50° C., L is a measured length of the sample at a temperature T, T₀ is equal to 50° C., and T is the temperature at which a measure is taken. The measures can be taken at each interval of 10° C., so that the correspondent LCTE (i.e., a) at each temperature can be calculated based on the above formula. The average LCTE can be further calculated by averaging the α values.

Hereafter, three temperature ranges 50° C.-200° C., 50° C.-350° C. and 50° C.-500° C. are applied as examples for calculating three α values, namely α₁, α₂ and α₃. Based on the measures, the average LCTE values and the variation of the LCTE in the different temperature ranges then can be calculated.

The calculated parameters are defined as follows:

(1) α₁=LCTE between 50° C. and 200° C.,

(2) α₂=LCTE between 50° C. and 350° C.,

(3) α₃=LCTE between 50° C. and 500° C. (wherein T₀ is 50° C. for α₁, α₂, α₃),

(4) R₁=α₃−α₁,

(5) R₂=α₃−α₂,

(6) |ΔR|=|R₂|=−|R₁|,

(7) LCTE variation (αₘₐₓ−αₘᵢₙ): while the sample is heated from 100° C. to 500° C., measures can be taken at each interval of 10° C., and the α values can be derived from the above LCTE formula, the variation of the LCTE being equal to the difference between the maximum and the minimum of the α values.

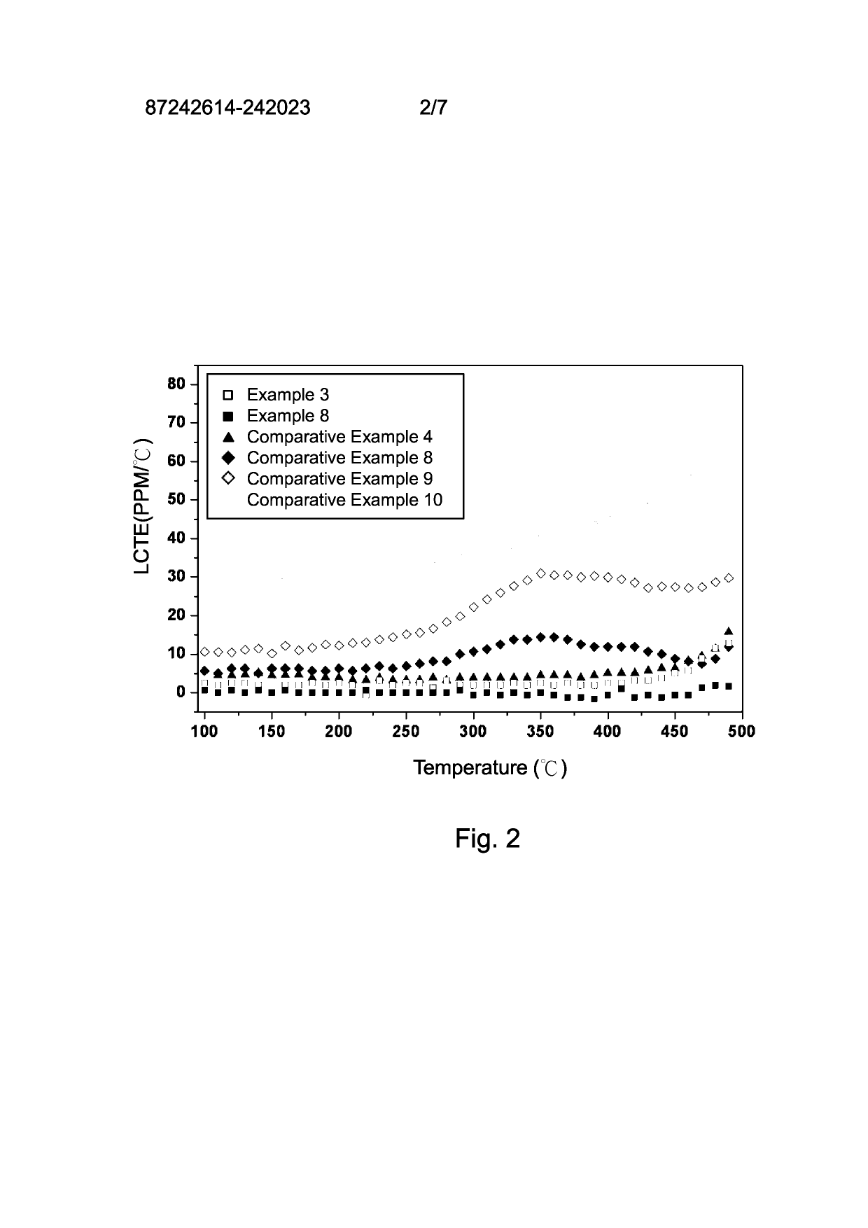

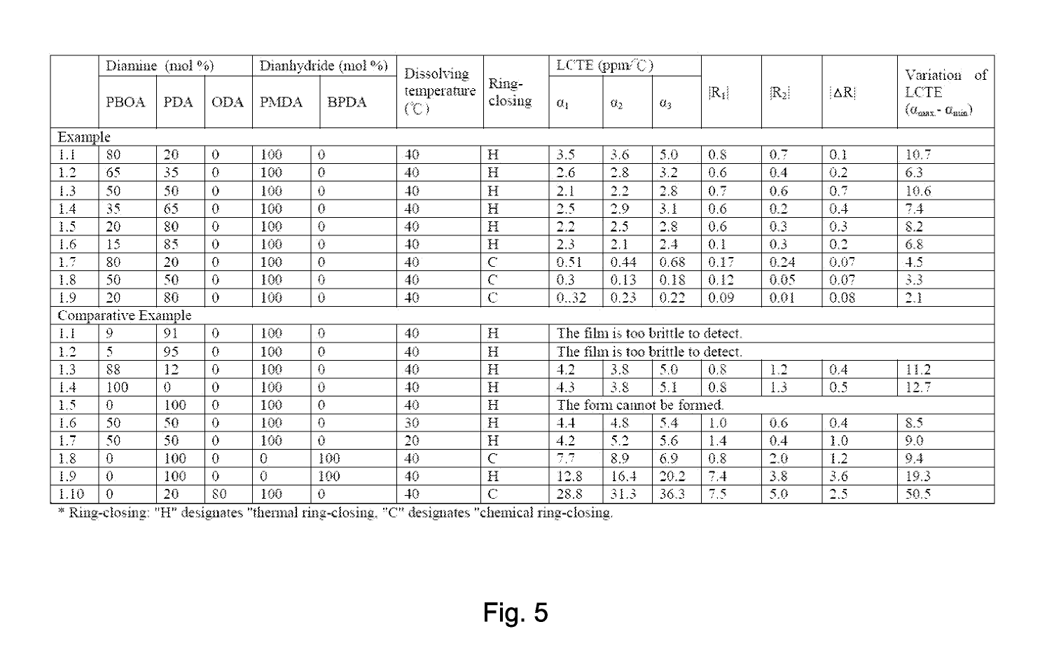

The results of the measures and computation are shown in the chart of FIG. 5. FIG. 2 is a graph plotting a variation of the LCTE for the testing applied on Examples 1.3 and 1.8, and Comparative Examples 1.4, 1.8, 1.9 and 1.10 (Comparative Example 1.5 is omitted because no film is formed).

Test of a Pyrolysis Temperature

A pyrolysis temperature can be measured by using a thermo gravimetric analyzer TGA (Q50) (sold by TA Instruments, Inc.). A sample can be heated from 50° C. to 800° C. at a heating rate equal to about 10° C./min. With a weight reference taken at the temperature of 50° C., the temperature T_{d}5% at which the sample is reduced by 5% of the total weight reference owing to pyrolysis can be determined from the TGA graph.

It can be observed that T_{d}5% for the aromatic polyimide films fabricated according to Examples 1.1 to 1.9 are all higher than about 600° C. T_{d}5% cannot be measured for Comparative Examples 1.1 and 1.2 owing to the formation of excessively brittle films, and T_{d}5% cannot be measured for Comparative Example 1.5 because no film is formed. Comparative Example 1.10 has a T_{d}5% higher than 580° C., and the remaining Comparative Examples have a T_{d}5% higher than 600° C.

For Examples 1.1 to 1.9, it can be observed that the aromatic polyimide films containing the benzoxazole functional group can have a lower LCTE value, and the variation of the LCTE under thermal stress can be substantially low. In particular, the LCTE variations can be lower than about 11 ppm/° C. in a temperature range between 50° C. and 500° C., for example lower than 8 ppm/° C., or more specifically lower than 4 ppm/° C. Furthermore, the aromatic polyimide films can exhibit excellent resistance to heat, and keep a low LCTE even at high temperatures (>350° C.).

In addition, it can be observed that the temperature at which the aromatic diamine is dissolved in the solvent may affect the properties of the polyimide film. When the temperature at which the aromatic diamine is dissolved is equal to or above about 40° C., the formed polyimide film can have a significantly low LCTE value. This can be shown by the testing results of Example 1.3 compared against Comparative Examples 1.6 and 1.7.

The aromatic polyimide films containing the benzoxazole functional group can be formed through a thermal or a chemical ring-closing reaction, and both of the ring-closing reactions can yield enhanced physical properties of the polyimide film. Referring to the chart of FIG. 2, compared to the Comparative Examples, Examples 1.3 and 1.8 can have LCTE values that are relatively lower, and LCTE variations under thermal stress that are significantly smaller, e.g., when the temperature is between 300° C. and 350° C. or even above. Moreover, the chemical ring-closing reaction (e.g., in Example 1.8) may produce an enhanced aromatic polyimide film that has a LCTE much less affected by a temperature change (the LCTE variations of the Examples can be lower than those of the Comparative Examples by about 3 to 15 times). With a LCTE that has no temperature dependency and is substantially stable, the aromatic polyimide films may be particularly suitable for high-temperature processing used in the manufacture of solar cells, OLED, plastic chips, and the like.

Preparation and Properties of the Laminate

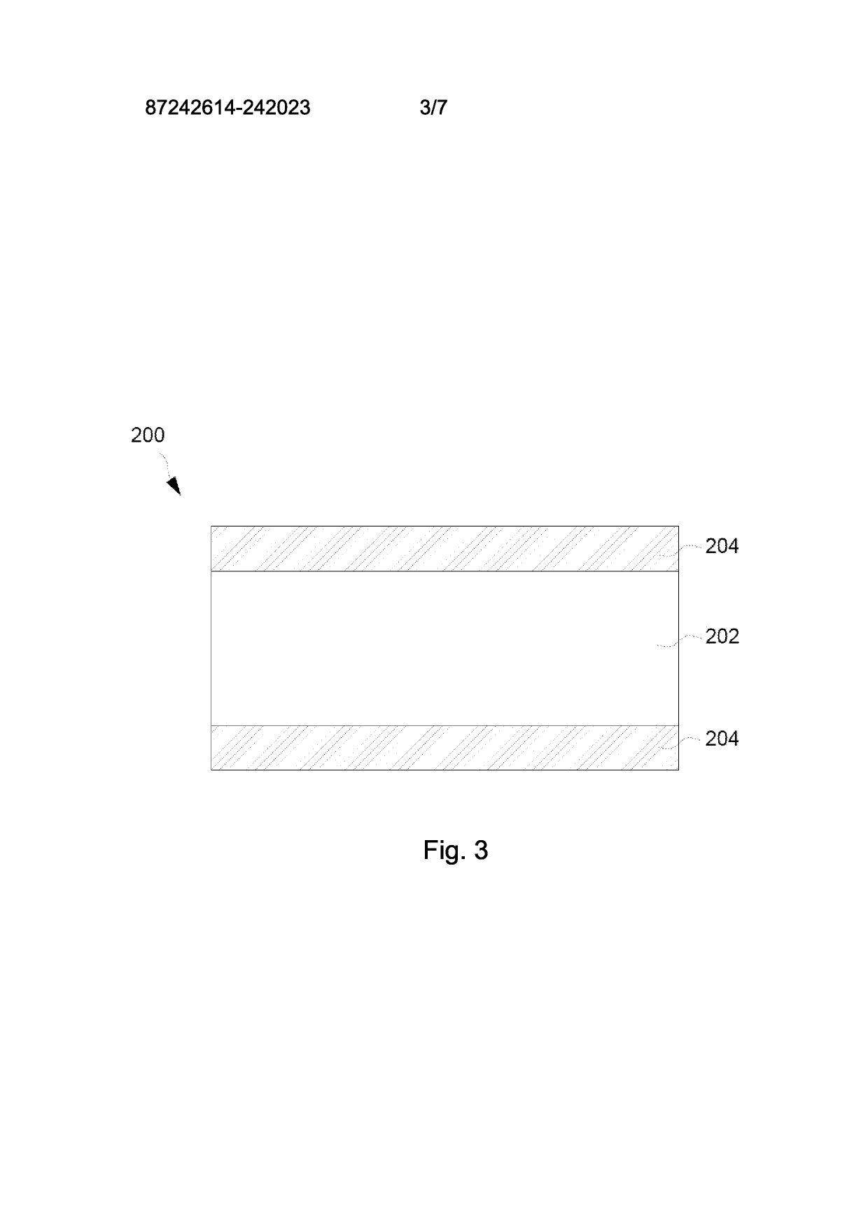

FIG. 3 is a schematic view illustrating one laminate embodiment using a polyimide. The laminate 200 can include a polyimide film 202, and metal layers 204 disposed on the two opposite surfaces of the polyimide film 202. The laminate 200 can be used in various applications such as flexible solar cells, flexible circuit boards, and the like. The polyimide film 202 and the metal layer 204 can be fabricated according to various manufacture processes described hereafter.

### Example 2.1

About 50.812 g of PBOA and about 400 g of DMAC can be added in a three-necked flask, and completely dissolved by agitation at a temperature equal to about 40° C. Then, about 49.188 g of PMDA can be incorporated in the mixture. The weight ratio of the monomers PBOA and PMDA can be 20 wt % of the total weight of the reaction mixture. The reaction mixture then can be continuously agitated for 20 hours at a temperature of 25° C. to form a PAA solution with a viscosity equal to about 140,000 cps.

The PAA solution can be coated onto a glass plate support, and baked in a furnace in a stepwise manner at about 80° C. for 30 minutes to remove the solvent, then between about 170° C. and about 420° C. for 4 hours to form a PBI polyimide film. The polyimide film having a thickness equal to about 50 μm can be peeled from the glass.

Next, molybdenum (Mo) can be deposited on the two opposite surfaces of the polyimide film by sputtering deposition. The sputtering deposition can be conducted with sputtering power of about 10 W, at a temperature equal to about 150° C., and under a pressure equal to about 5×10⁻⁶ torr. The thickness of the Mo layers can depend on the duration and number of times of the sputtering deposition. In one example, each Mo layer may have a thickness equal to about 0.4 μm.

### Example 2.2

A laminate can be prepared like in Example 2.1, wherein two species of diamines can be used for forming the polyimide film: the monomers can include, for example, about 48.918 g of PBOA, about 1.235 g of PDA, and about 49.847 g of PMDA. The weight ratio of the monomers can be about 20 wt % of the total weight of the reaction solution, the PBOA:PDA molar ratio can be equal to about 95:5, and the Mo layers can have a thickness equal to about 0.4 μm.

### Example 2.3

A laminate can be prepared like in Example 2.1, wherein two species of diamines can be used for forming the polyimide film: the monomers can include, for example, about 42.92 g of PBOA, about 5.146 g of PDA, and about 51.934 g of PMDA. The weight ratio of the monomers can be about 20 wt % of the total weight of the reaction solution, the PBOA:PDA molar ratio can be about 80:20, and the Mo layers can have a thickness equal to about 0.4 μm.

### Example 2.4

A laminate can be prepared like in Example 2.1, wherein two species of diamines are used for forming the polyimide film: the monomers can include, for example, about 36.397 g of PBOA, about 9.399 g of PDA, and about 54.205 g of PMDA. The weight ratio of the monomers can be about 20 wt % of the total weight of the reaction solution, the PBOA:PDA molar ratio can be about 65:35, and the Mo layers can have a thickness equal to about 0.4 μm.

### Example 2.5

A laminate can be prepared like in Example 2.2, wherein the used monomers can include, for example, about 29.277 g of PBOA, about 14.041 g of PDA, and about 56.682 g of PMDA. The weight ratio of the monomers can be about 20 wt % of the total weight of the reaction solution, the PBOA:PDA molar ratio can be about 50:50, and the Mo layers can have a thickness equal to about 0.4 μm.

### Example 2.6

A laminate can be prepared like in Example 2.2, wherein two species of diamines can be used for forming the polyimide film: the monomers can include, for example, about 21.476 g of PBOA, about 19.127 g of PDA, and about 59.397 g of PMDA. The weight ratio of the monomers can be equal to about 20 wt % of the total weight of the reaction solution, the PBOA:PDA molar ratio can be about 35:65, and the Mo layers can have a thickness equal to about 0.4 μm.

### Example 2.7

A laminate can be prepared like in Example 2.2, wherein two species of diamines can be used for forming the polyimide film: the monomers can include, for example, about 21.476 g of PBOA, about 19.127 g of PDA, and about 59.397 g of PMDA. The weight ratio of the monomers can be equal to about 20 wt % of the total weight of the reaction solution, the PBOA:PDA molar ratio can be about 15:85, and the Mo layers can have a thickness equal to about 0.4 μm.

### Example 2.8

A laminate can be prepared like in Example 2.2, wherein two species of diamines can be used for forming the polyimide: the monomers can include, for example, 48.409 g of PBOA, 2.263 g of ODA, and 49.328 g of PMDA. The weigh ratio of the monomers can be about 20 wt % of the total weight of the reaction solution, the PBOA:ODA molar ratio can be about 95:5, and the Mo layers can have a thickness equal to about 0.4 μm.

### Example 2.9

A laminate can be prepared like in Example 2.2, wherein two species of diamines can be used for forming the polyimide film: the monomers can include, for example, about 45.993 g of PBOA, about 4.538 g of ODA, and about 49.469 g of PMDA. The weight ratio of the monomers can be equal to about 20 wt % of the total weight of the reaction solution, the PBOA:ODA molar ratio can be about 90:10, and the Mo layers can have a thickness equal to about 0.4 μm.

### Example 2.10

A laminate can be prepared like in Example 2.2, wherein three species of diamines can be used for forming the polyimide film: the monomers can include, for example, about 27.625 g of PBOA, about 6.624 g of PDA, about 12.267 g of ODA, and about 53.484 g of PMDA. The weight ratio of the monomers can be equal to about 20 wt % of the total weight of the reaction solution, the PBOA:PDA:ODA molar ratio can be about 50:25:25, and the Mo layers can have a thickness equal to about 0.4 μm.

### Example 2.11

About 50.812 g of PBOA and about 400 g of DMAC can be incorporated in a three-necked flask, and completely dissolved by agitation at a temperature equal to about 40° C. Then, about 49.188 g of PMDA can be incorporated. The weight ratio of the monomers PBOA and PMDA can be about 20 wt % of the total weight of the reaction solution. The reaction mixture can be continuously agitated for 20 hours at a temperature of about 25° C. for forming a PAA solution with a viscosity equal to about 140,000 cps.

A chemical ring-closing reaction then can be applied. A dehydrant acetic anhydride and a catalyst picoline can be added and mixed homogeneously, wherein the PAA:acetic anhydride:picoline molar ratio is equal to about 1:2:1. The PAA solution then can be coated onto a glass plate support, and baked in a furnace in a stepwise manner at about 80° C. for 30 minutes to remove the solvent, then between about 170° C. and about 420° C. for 4 hours to form a polyimide film containing the PBI and having a thickness equal to about 50 μm. Subsequently, the Mo layers can be deposited like Example 2.1.

### Example 2.12

A laminate can be prepared like in Example 2.11, wherein two species of diamines can be used for forming the polyimide film: the monomers can include, for example, about 29.277 g of PBOA, about 14.041 g of PDA, and about 56.682 g of PMDA. The weight ratio of the monomers can be about 20 wt % of the total weight of the reaction solution, the PBOA:PDA molar ratio can be about 50:50, and the Mo layers can have a thickness equal to about 0.4 μm.

### Example 2.13

A laminate can be prepared like in Example 2.1, wherein the Mo layers can have a thickness equal to about 1 μm.

### Example 2.14

A laminate can be prepared like in Example 2.11, wherein the Mo layers can have a thickness equal to about 1 μm.

### Comparative Example 2.1

A laminate can be prepared like in Example 2.1, wherein the used monomers can include about 41.117 g of PBOA, about 9.129 g of ODA, and about 49.754 g of PMDA. The weight ratio of the monomers can be about 20 wt % of the total weight of the reaction solution, the PBOA:ODA molar ratio can be about 80:20, and the Mo layers can have a thickness equal to about 0.4 μm.

### Comparative Example 2.2

A laminate can be prepared like in Example 2.1, wherein the used monomers can include about 33.699 g of PBOA, about 16.115 g of ODA, and about 50.186 g of PMDA. The weight ratio of the monomers can be about 20 wt % of the total weight of the reaction solution, the PBOA:ODA molar ratio can be about 65:35, and the Mo layers can have a thickness equal to about 0.4 μm.

### Comparative Example 2.3

A laminate can be prepared like in Example 2.1, wherein the used monomers can include about 26.15 g of PBOA, about 23.222 g of ODA, and about 50.627 g of PMDA. The weight ratio of the monomers can be about 20 wt % of the total weight of the reaction solution, the PBOA:ODA molar ratio can be about 50:50, and the Mo layers can have a thickness equal to about 0.4 μm.

### Comparative Example 2.4

A laminate can be prepared like in Example 2.1, wherein the used monomers can include about 10.647 g of PBOA, about 37.821 g of ODA, and about 51.532 g of PMDA. The weight ratio of the monomers can be about 20 wt % of the total weight of the reaction solution, the PBOA:ODA molar ratio can be about 20:80, and the Mo layers can have a thickness equal to about 0.4 μm.

### Comparative Example 2.5

A laminate can be prepared like in Example 2.1, wherein the used monomers can include about 2.686 g of PBOA, about 45.318 g of ODA, and about 51.996 g of PMDA. The weight ratio of the monomers can be about 20 wt % of the total weight of the reaction solution, the PBOA:ODA molar ratio can be about 5:95, and the Mo layers can have a thickness equal to about 0.4 μm.

### Comparative Example 2.6

A laminate can be prepared like in Example 2.1, wherein the used monomers can include about 33.129 g of PDA and about 66.871 g of PMDA. The weight ratio of the monomers can be equal to about 20 wt % of the total weight of the reaction solution. It can be observed that the polyimide formed according to this Comparative Example 2.6 is excessively brittle and cannot provide an effective film.

### Comparative Example 2.7

A laminate can be prepared like in Example 2.1, wherein the used monomers can include about 47.847 g of ODA, and about 52.153 g of PMDA. The weight ratio of the monomers can be equal to about 20 wt % of the total weight of the reaction solution, and the Mo layers can have a thickness equal to about 0.4 μm.

### Comparative Example 2.8

A laminate can be prepared like in Example 2.1, wherein the used monomers can include about 14.516 g of PDA, about 26.882 g of ODA, and about 58.602 g of PMDA. The weight ratio of the monomers can be equal to about 20 wt % of the total weight of the reaction solution, the PDA:ODA molar ratio can be about 50:50, and the Mo layers can have a thickness equal to about 0.4 μm.

### Comparative Example 2.9

A laminate can be prepared like in Example 2.1, wherein the Mo layers can have a thickness equal to about 1.5 μm.

### Comparative Example 2.10

A laminate can be prepared like in Example 2.11, wherein the Mo layers can have a thickness equal to about 1.5 μm.

The properties of the laminates fabricated according to the aforementioned Examples and Comparative Examples can be tested as described hereafter.

Size Variation of the Polyimide Film in the Laminate

A polyimide film with no Mo layer can be used for this test. The size variation can be measured by using a thermal mechanical analyzer TMAQ400 (sold by TA Instruments, Inc.). In nitrogen atmosphere, a sample of the polyimide film with a surface dimension equal to about 15 mm×4 mm can be heated from 25° C. to 500° C. at a heating rate of about 20° C./min, and then cooled down from 500° C. to 25° C. at a cooling rate of about 20° C./min. Next, a second thermal process with the same conditions can be conducted to heat the polyimide film from 25° C. to 500° C., and the size of the sample can be measured at 25° C. and 500° C. The testing data obtained from the second thermal process can avoid biasing effects induced by residual stress.

An absolute value of the size variation (x) can be derived from the following formula:

|x|=|(L−L₀)/L₀|×100%

wherein L₀ is a length of the sample at 25° C., and L is the length of the sample at 500° C.

Testing Applied on the Laminate

(1) Testing of the Surface Characteristics Under Thermal Stress:

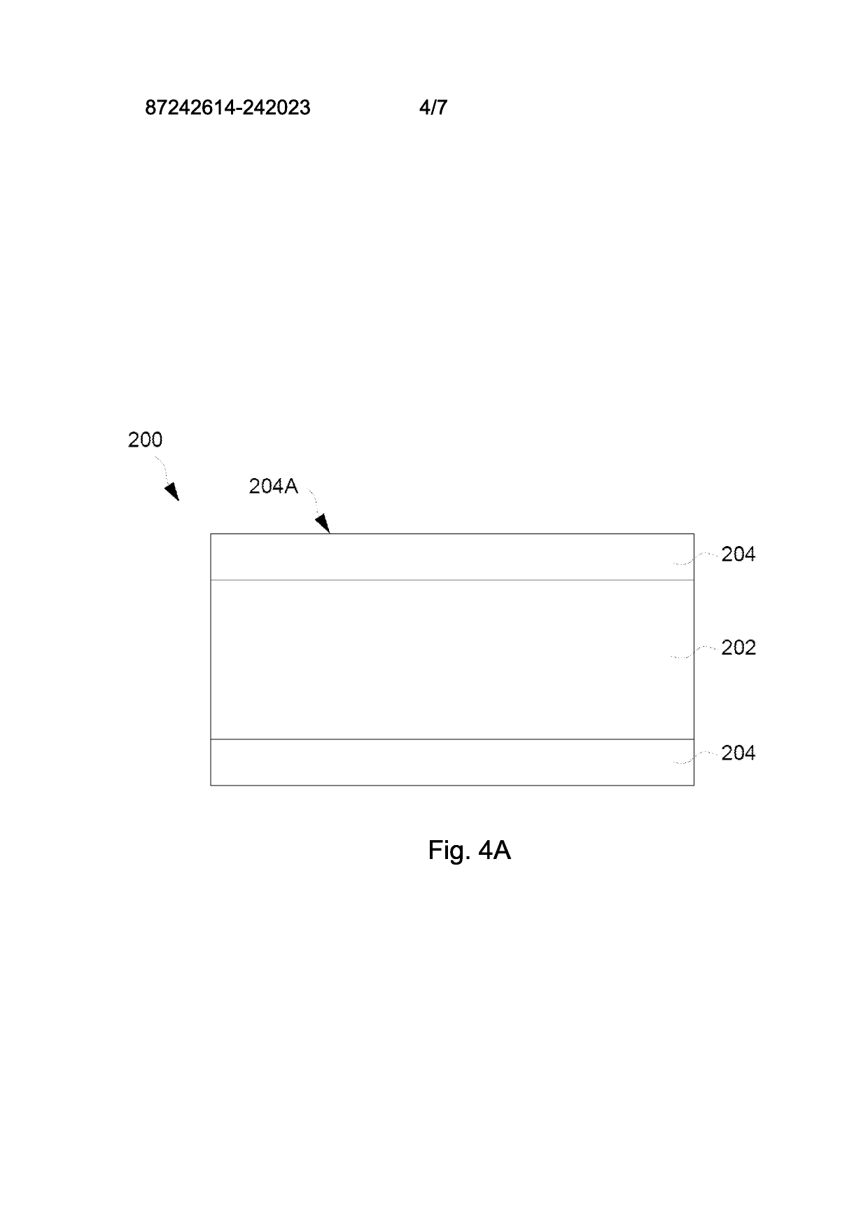

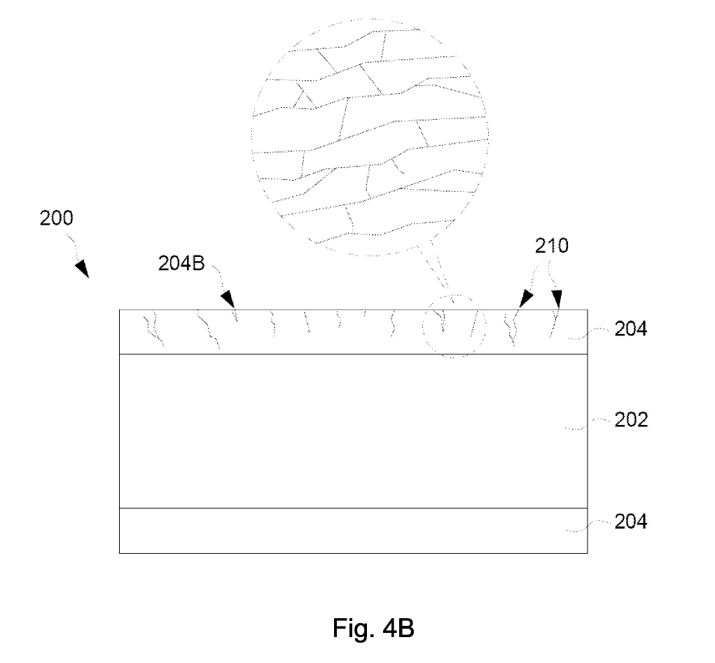

10 cm×10 cm of a polyimide film with the Mo layers thereon can be used as a test sample. In a rapid thermal processing oven, the sample can be heated under a low pressure of about 10⁻² torr from an ambient temperature to about 550° C. with a heating rate equal to about 150° C./min, can be kept at the temperature of 550° C. for 5 minutes, and then cooled down to the ambient temperature. After cooling, the sample can be examined with an optical microscope to detect the occurrence of cracks on the Mo layers. The surface characteristics for Example 2.11 and Comparative Example 2.9 after heat treatment are respectively illustrated in FIGS. 4A and 4B.

(2) Measure of a Warp of the Sample:

After undergoing the aforementioned heat treatment, the sample can be placed on a flat support surface. The flat support surface can be used as a reference surface, and the distances between the reference surface and each of four corners of the sample (i.e., characterizing upward warping) can be measured. The measure data at the four corners can be averaged to derive a warp of the sample.

(3) Testing of the Sheet Resistance of the Laminate:

The sheet resistance can be measured by using a low resistivity meter MCP-T600 (sold by Mitsubishi Chemical Holdings, Japan).

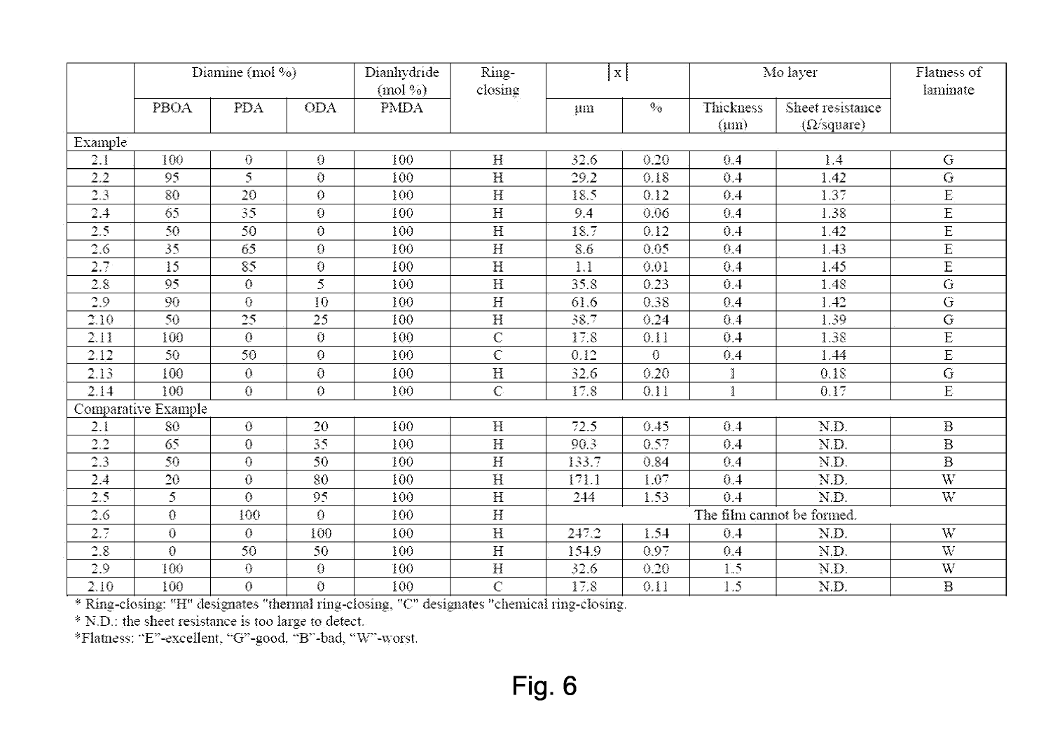

FIG. 6 is a chart illustrating the results of the testing and measures obtained from the aforementioned deformation testing (1) to (3). In FIG. 6, the laminate flatness can be evaluated as follows:

Excellent (“E”): no crack on the Mo layer, and the warp is equal or less than 0.1 cm;

Good (“G”): no crack on the Mo layer, and 0.1 cm<the warp ≦0.5 cm.

Bad (“B”): occurrence of cracks on the Mo layer, and 0.5 cm<the warp ≦1.0 cm; and

Worst (“W”): occurrence of cracks on the Mo layer, and 1.0 cm<the warp.

As shown in the chart of FIG. 6, the laminates fabricated according to Examples 2.1 to 2.14 can generally exhibit enhanced dimension stability, especially the laminates where only PBOA is used as diamine to make the polyimide film (e.g., Examples 2.1, 2.11, 2.13 and 2.14), and the laminates where a combination of PBOA with one or two of PDA and ODA at a specific ratio as diamine components to make the polyimide film (e.g., Examples 2.2 to 2.10, and 2.12). The aromatic polyimide films can have a small size variation, even when subjected to high temperature treatment. As a result, the metal layer can be disposed on a polyimide film that is highly stable under thermal stress, which can reduce or eliminate the occurrence of cracks or defects induced by deformation of the polyimide film.

In addition, it can be observed that the implementation of thermal and chemical ring-closing reactions may also improve the dimensional stability of the aromatic polyimide film (e.g., as shown in Examples 2.1, 2.5, 2.11 and 2.12). For obtaining a desired dimensional stability, the aromatic polyimide film should have a size variation that is lower than 0.45% in absolute value, i.e., |x| smaller than 0.45%. When |x| increases (e.g., to about 0.45-1.52% in Comparative Examples 2.1 to 2.8), the laminates may have very poor flatness. Moreover, a metal layer having thickness lower than 1 μm can also prevent crack formation, laminate bending, and high sheet resistance (e.g. Examples 2-1, 2-13 and Comparative Examples 2-9, 2-10).

FIG. 4A illustrates a laminate formed according to Example 2-11, and FIG. 4B illustrates a laminate formed according to Comparative Example 2-9. After high temperature treatment, the metal layer surface 204A shown in FIG. 4A is complete and flat, whereas significant cracks are formed on the metal layer surface 204B shown in FIG. 4B.

The laminates fabricated according to the examples described herein can exhibit good resistance to heat, good size stability, and good flatness and electric conduction. Applications of the polyimide and laminate films can include, without limitation, solar cells, OLED, plastic chips and the like, in which high temperature fabrication steps are applied. In particular, solar cells (such as CIGS (copper indium gallium diselenide) solar cells) incorporating the laminates may have improved efficiency in photoelectric conversion.

Realizations of the polyimide films, laminates and related fabrication methods have been described in the context of particular embodiments. These embodiments are meant to be illustrative and not limiting. Many variations, modifications, additions, and improvements are possible. These and other variations, modifications, additions, and improvements may fall within the scope of the inventions as defined in the claims that follow.

What is claimed is:

1. An aromatic polyimide film formed from a plurality of monomers comprising:
an aromatic dianhydride; and
a first aromatic diamine selected from a group consisting of formulae (I) and (II): 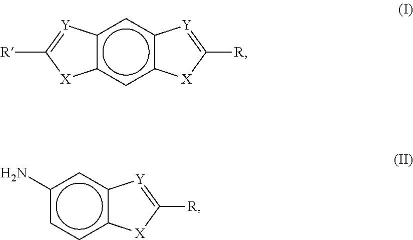
wherein X and Y are respectively selected from the group consisting of oxygen, nitrogen and sulfur, and
R and R′ are respectively selected from the group consisting of NH₂, 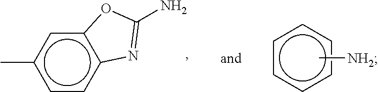
wherein the aromatic polyimide film has an average linear coefficient of thermal expansion equal to or below about 5 ppm/° C. in a temperature range between about 50° C. and about 500° C.

2. The aromatic polyimide film according to claim 1, wherein the monomers further include a second aromatic diamine selected from a group consisting of p-phenylenediamine (PDA), 4,4′-oxydianiline (4,4′-ODA), diaminodiphenyl ether (3,4-DAPE), diaminodiphenyl sulfone (DDS) and 4,4′-diamino-triphenyamine.

3. The aromatic polyimide film according to claim 1, wherein a variation of the linear coefficient of thermal expansion in a temperature range between 100° C. and about 500° C. is equal to or smaller than about 11 ppm/° C.

4. The aromatic polyimide film according to claim 1, wherein the average linear coefficient of thermal expansion is between about 0.1 ppm/° C. and about 4.5 ppm/° C. in a temperature range between 50° C. and 500° C.

5. The aromatic polyimide film according to claim 1, wherein the monomers further include a second aromatic diamine, a molar ratio of the first aromatic diamine is equal to or greater than about 15 mol % based on a total amount of diamines, and the second aromatic diamine is equal to or less than about 85 mol % based on the total amount of diamines.

6. The aromatic polyimide film according to claim 1, wherein the first aromatic diamine is 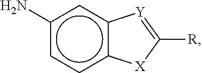
X being oxygen, Y being nitrogen, and
R being selected from the group consisting of NH₂,

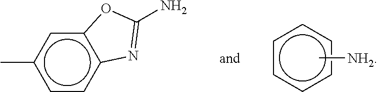

7. The aromatic polyimide film according to claim 1, wherein the monomers further include a second aromatic diamine that is selected from a group consisting of p-phenylenediamine, 4,4′-oxydianiline, and a combination thereof.

8. The aromatic polyimide film according to claim 1, wherein the aromatic dianhydride is selected from a group consisting of 3,3′,4,4′-biphenyl tetracarboxylic dianhydride (BPDA), pyromellitic dianhydride (PMDA), 3,3′,4,4′-benzophenone tetracarboxylic dianhydride (BTDA), 2,2′-bis-(3,4-dicarboxyphenyl)hexafluoropropane FDA), 4,4′-oxydiphthalic anhydride (ODPA), 3,3′,4,4′-diphenylsulfone tetracarboxylic dianhydride (DSDA), bis(3,4-dicarboxyphenyl)sulfone, 5(2,5-dioxotetrahydrol)-3-methyl-3-cyclohexane-1,2-dicarboxylic anhydride, ethylene glycol bis(anhydro-trimellitate), and 2,3,3′,4′-biphenyl tetracarboxylic anhydride.

9. A laminate comprising:
the aromatic polyimide film according to claim 1; and
at least one conductive layer disposed on a surface of the aromatic polyimide film.

10. The laminate according to claim 9, wherein the conductive layer is a metal layer including Cu, Al, Au, Zn, Ga, In, Sn, Ag, Pd, Ni, Pt, Cr, Mo, W, and any alloy thereof.

11. The laminate of claim 9, wherein the first aromatic diamine has the formula (II), in which X is oxygen, Y is nitrogen, and R is

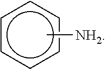

12. The laminate according to claim 11, wherein the aromatic polyimide film further comprises a second aromatic diamine selected from one of the following:
PDA, wherein a molar ratio of the first aromatic diamine:PDA is equal to about 99-15:1-85;
4,4′-ODA, wherein a molar ratio of the first aromatic diamine:4,4′-ODA is about 99-90:1-10; and
a combination of PDA and 4,4′-ODA, wherein a molar ratio of the first aromatic diamine:PDA:4,4′-ODA is equal to about 98-15:1-60:1-25.

13. The laminate according to claim 12, wherein the aromatic polyimide film has a size variation that is less than 0.45% in absolute value in a temperature range between 25° C. and 500° C.

14. A flexible solar cell comprising a laminate according to claim 10.

15. A display comprising:
a panel; and
a flexible film electrically connecting with the panel, the flexible comprising:
an aromatic polyimide film of claim 1;
a metal layer with a circuit pattern printed thereon disposed on the aromatic polyimide film; and
a chip disposed on the metal layer.

16. A method of fabricating an aromatic polyimide film, comprising:
dissolving an aromatic diamine in an solvent at a temperature equal to or higher than about 40° C.;
performing condensation polymerization applied on the aromatic diamine and an aromatic dianhydride to obtain a polyamic acid solution;
coating a layer of the polyamic acid solution on a support; and
baking the coated layer to form an aromatic polyimide film.

17. The method according to claim 16, wherein the aromatic diamine comprises two species of aromatic diamines.

18. The method according to claim 16, wherein the aromatic polyimide film has a size variation that is equal to or less than about 0.45% in absolute value in a temperature range between 25° C. and 500° C.

19. The method according to claim 16, further comprising adding a dehydrant and a catalyst into the polyamic acid solution before coating a layer of the polyamic acid solution on a support.

20. The method according to claim 19, wherein the catalyst is selected from a group consisting of heterocyclic tertiary amines, aliphatic tertiary amines, and aromatic tertiary amines.

21. The method according to claim 19, wherein the dehydrant is selected from a group consisting of aliphatic acid anhydrides and aromatic acid anhydrides.

22. The method according to claim 16, further comprising heating the polyamic acid solution between 60° C. and 100° C. before baking the coated layer.

23. The method according to claim 16, wherein the baking temperature is between about 150° C. and about 450° C.

24. The method according to claim 16, wherein the aromatic diamine has the structure 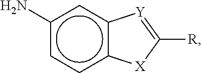
wherein X is oxygen, Y is nitrogen, and R is selected from a group consisting of NH₂,

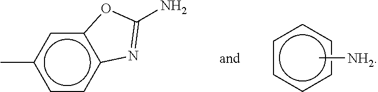

25. The method according to claim 16, wherein the aromatic diamine is PDA, 4,4′-ODA, or a combination thereof.

26. The method according to claim 16, wherein the aromatic dianhydride is selected from a group consisting of 3,3′,4,4′-biphenyl tetracarboxylic dianhydride (BPDA), pyromellitic dianhydride (PMDA), 3,3′,4,4′-benzophenone tetracarboxylic dianhydride (BTDA), 2,2′-bis-(3,4-dicarboxyphenyl)hexafluoropropane (6FDA), 4,4′-oxydiphthalic anhydride (ODPA), 3,3′,4,4′-diphenylsulfone tetracarboxylic dianhydride (DSDA), bis(3,4-dicarboxyphenyl)sulfone, 5(2,5-dioxotetrahydrol)-3-methyl-3-cyclohexane-1,2-dicarboxylic anhydride, ethylene glycol bis(anhydro-trimellitate), and 2,3,3′,4′-biphenyl tetracarboxylic anhydride.
